(19) United States
(12) Patent Application Publication
(10) Pub. No.: US 2007/0076471 A1
(43) Pub. Date: Apr. 5, 2007

(54) STORAGE ELEMENT AND MEMORY

(76) Inventors: Hiroshi Kano, Kanagawa (JP); Masanori Hosomi, Kanagawa (JP)

Correspondence Address: David R. Metzger;SONNENSCHEIN NATH & ROSENTHAL LLP, Post Office Box 061080, Wacker Drive Station, Sears Tower, Chicago, IL, 60606-1080, US

(21) Appl. No.: 11/535,126

(22) Filed: Sep. 26, 2006

(30) Foreign Application Priority Data
Sep. 30, 2005 (JP) P2005-288557

(51) Int. Cl. G11C 11/00

(52) U.S. Cl. 365/158

(57) ABSTRACT

A storage element includes a storage layer which holds information based on a magnetization state of a magnetic body, an upper pinned magnetic layer disposed above the storage layer with an upper intermediate layer therebetween, and a lower pinned magnetic layer disposed below the storage layer with a lower intermediate layer therebetween, wherein one of the upper intermediate layer and the lower intermediate layer is an insulating layer which forms a tunnel barrier, the other intermediate layer is a laminate including an insulating layer and a nonmagnetic conductive layer, and the magnetization direction of the storage layer is varied by passing a current through the storage element in the lamination direction to enable recording of information on the storage layer.

### CROSS REFERENCES TO RELATED APPLICATIONS

The present invention contains subject matter related to Japanese Patent Application JP 2005-288557 filed in the Japanese Patent Office on Sep. 30, 2005, the entire contents of which are incorporated herein by reference.

### BACKGROUND OF THE INVENTION

1. Field of the Invention

The present invention relates to a storage element including a storage layer for storing a magnetization state as information and a pinned magnetic layer whose magnetization direction is pinned, the magnetization direction of the storage layer being varied by the application of a current, and a memory including the storage element. The invention is suitable for use in nonvolatile memories.

2. Description of the Related Art

In information apparatuses, such as computers, DRAMs which operate at high speed and have high densities are widely used as random-access memories. However, DRAMs are volatile memories that lose stored information when power is disconnected. Thus, there is a need for nonvolatile memories that do not lose stored information even if power is disconnected.

As a promising nonvolatile memory, magnetic random-access memories (MRAMs), which record information using the magnetization of magnetic materials, have been receiving attention, and development thereof has been making progress (for examples, refer to Nikkei Electronics, Feb. 12, 2001, pp. 164-171 (Non-patent Document 1)).

In an MRAM, two types of address wiring (word lines and bit lines) are arranged substantially perpendicular to each other, and a magnetic storage element is disposed at each crossover of these address wirings. When a current is allowed to flow through each of the address wirings, the magnetization of the magnetic layer of the magnetic storage element is reversed by the current-induced magnetic field generated from each address wiring to record information.

FIG. 5 is a schematic perspective view of a known MRAM.

As shown in FIG. 5, a drain region 108, a source region 107, and a gate electrode 101 which constitute a selecting transistor for selecting a memory cell are disposed in each of the sections of a semiconductor substrate 110, such as a silicon substrate, the sections being isolated by element isolation layers 102.

Furthermore, a word line 105 extending toward the back of the drawing is provided above the gate electrode 101.

The drain region 108 is designed so as to be shared by two adjacent selecting transistors in the row direction, and a wiring 109 is connected to the drain region 108.

A magnetic storage element 103 having a storage layer whose magnetization direction is subjected to reversal is disposed between the word line 105 and a bit line 106 extending in the row direction above the magnetic storage element 103. The magnetic storage element 103 is, for example, composed of a magnetic tunnel junction element (MTJ element).

Furthermore, the magnetic storage element 103 is electrically connected to the source region 107 through a bypass line 111 extending in the horizontal direction and a contact layer 104 extending in the vertical direction.

By allowing a current to flow through each of the word line 105 and the bit line 106, a current-induced magnetic field is applied to the magnetic storage element 103, and thus the magnetization direction of the storage layer of the magnetic storage element 103 is reversed to enable recording of information.

In a magnetic memory, such as an MRAM, in order to stably retain recorded information, a magnetic layer (storage layer) that records information needs to have certain coercivity.

In the meantime, in order to rewrite recorded information, it is necessary to allow a certain amount of current to flow through the address wirings. However, as the size of the elements constituting the MRAM is reduced, the address wirings become thinner, and as a result, it becomes difficult to allow a sufficient amount of current to flow therethrough.

Under these circumstances, a memory having a structure using magnetization reversal by spin injection, as a structure in which magnetization can be reversed by a smaller amount of current, has been receiving attention (for examples, refer to Japanese Unexamined Patent Application Publication No. 2003-17782 (Patent Document 1)).

In the magnetization reversal by spin injection, by injecting electrons that have been passed through a first magnetic body and spin-polarized into a second magnetic body, magnetization reversal is allowed to occur in the second magnetic body.

For example, in a giant magnetoresistive element (GMR element) or a magnetic tunnel junction element (MTJ element), by allowing a current to flow through the element in a direction perpendicular to the plane thereof, it is possible to reverse the magnetization direction of at least some of the magnetic layers.

The magnetization reversal by spin injection has an advantage in that even if the size of the elements is reduced, magnetization reversal can be achieved without increasing current levels.

FIG. 3 is a schematic perspective view of a memory having the structure using magnetization reversal by spin injection, and FIG. 4 is a cross-sectional view of the memory shown in FIG. 3.

As shown in FIGS. 3 and 4, a drain region 58, a source region 57, and a gate electrode 51 which constitute a selecting transistor for selecting a memory cell are disposed in each of the sections of a semiconductor substrate 60, such as a silicon substrate, the sections being isolated by element isolation layers 52. The gate electrode 51 also serves as a word line extending toward the back.

The drain region 58 is designed so as to be shared by two adjacent selecting transistors in the row direction, and a wiring 59 is connected to the drain region 58.

A storage element 53 having a storage layer whose magnetization direction is reversed by spin injection is disposed between the source region 57 and a bit line 56 extending in the row direction above the storage element 53.

The storage element 53 is, for example, composed of a magnetic tunnel junction element (MTJ element). Referring to FIG. 4, reference numerals 61 and 62 each denote a magnetic layer. One of the magnetic layers 61 and 62 is a pinned magnetic layer whose magnetization direction is pinned, and the other magnetic layer is a free magnetic layer, i.e., storage layer, in which the magnetization direction is varied.

Furthermore, the storage element 53 is connected to the bit line 56 and the source region 57 through the upper and lower contact layers 54, respectively. Thus, by passing a current through the storage element 53, the magnetization direction of the storage layer can be reversed by spin injection.

The memory having the structure using magnetization reversal by spin injection is characterized in that the device structure can be simplified compared with the known MRAM shown in FIG. 5.

Another advantage is that, by using magnetization reversal by spin injection, the amount of write current is not increased even if the size of the elements is further reduced, compared with the known MRAM in which magnetization is reversed by an external magnetic field.

In the memory having the structure using magnetization reversal by spin injection, in order to further suppress power consumption, it is necessary to decrease the amount of input current by improving the spin injection efficiency.

Furthermore, in order to increase the strength of the read signal, it is necessary to ensure a large rate of change in magnetoresistance, and for that purpose, it is effective to dispose tunnel barrier layers as intermediate layers in contact with both surfaces of the storage layer.

In such a case, in view of the withstand voltage limit of the barrier layers, it is also necessary to decrease the amount of current during spin injection.

In order to decrease the amount of current during spin injection, a structure is proposed in which a storage element is designed to include the following laminate: pinned magnetic layer/intermediate layer/storage layer/intermediate layer/pinned magnetic layer, wherein the magnetization directions of the pinned magnetic layers provided above and below the storage layer are opposite each other (refer to U.S. patent application Ser. No. 2004/0027853 (Patent Document 2) and Japanese Unexamined Patent Application Publication No. 2004-193595 (Patent Document 3)).

In Patent Documents 2, etc., it is shown that the spin injection efficiency can be doubled by setting the magnetization directions of the upper and lower pinned magnetic layers to be opposite each other.

### SUMMARY OF THE INVENTION

In Patent Documents 2 and 3 described above, as the intermediate layer, either a nonmagnetic conductive layer or an insulating layer serving as a tunnel barrier layer is used. That is, possible combinations of the lower intermediate layer under the storage layer and the upper intermediate layer on the storage layer are the following four combinations: conductive layer/conductive layer, conductive layer/insulating layer, insulating layer/conductive layer, and insulating layer/insulating layer.

In the spin injection phenomenon, it has been theoretically derived that the threshold current that causes magnetization reversal can be given by Expression 1 below. If this expression is used, it is theoretically calculated that an increase in the damping constant leads to an increase in the threshold current (refer to J. Z. Sun, Phys. Rev. B, Vol. 62, p. 570, 2000).

$$Ic = \frac{1}{η} ( \frac{2 e}{h} ) \frac{α}{\vert cos ϕ \vert} ( {a}^{2} {I}_{m} {H}_{k} {M}_{s} ) ( 1 + \frac{2 π {M}_{s}}{{H}_{k}} + \frac{H}{{H}_{k}} ) \qquad ( Expression 1 )$$

where α is the damping constant of the storage layer, Hₖ is the uniaxially anisotropic magnetic field of the storage layer, Mₛ is the saturation magnetization of the storage layer, and η is the spin injection coefficient.

When the structure proposed in Patent Document 2 or the like is put into practice, the intermediate layers in contact with the storage layer and the pinned magnetic layers affect the damping constant of the storage layer because of the phenomenon referred to as “spin pumping”. It has been reported that the damping constant of the storage layer is increased by the materials constituting the intermediate layers and the pinned magnetic layers (for example, refer to Yaroslav et al., Phys. Rev. B, Vol. 66, p. 224403, 2002).

In particular, when one of the intermediate layers is composed of a nonmagnetic conductor, it is not possible to decrease the threshold current under the influence of the increase in the damping constant of the storage layer.

In contrast, when a tunnel insulating layer is used as each intermediate layer, the influence of the spin pumping is absent, and thus the damping constant of the storage layer is not increased.

However, a problem of a decrease in the magnetoresistance effect occurs.

In the case where the magnetization directions of the upper and lower pinned magnetic layers are set antiparallel to each other, as in Patent Document 2, the relationship θ1=180°−θ2 is satisfied, where θ1 is the relative angle between the magnetization direction of the storage layer and the magnetization direction of one pinned magnetic layer, and θ2 is the relative angle between the magnetization direction of the storage layer and the magnetization direction of the other pinned magnetic layer.

The magnetoresistance MR is given by the expression MR=Rs+ΔRx(1−cos θ)/2, using the angle θ between the magnetization direction of the pinned magnetic layer and the magnetization direction of the storage layer. In the expression, the term ΔRx represents the component that varies according to the magnetization direction of the storage layer, i.e., the change in resistance due to the magnetoresistance effect.

However, since cos θ2=cos(180°−θ1)=−cos θ1, the changes in resistance due to the magnetoresistance effect are opposite between the upper and lower pinned magnetic layers, and thus the magnetoresistance effects are counteracted.

That is, when tunnel insulating layers are used for both intermediate layers, the magnetoresistance effect is decreased due to counteraction, resulting in a decrease in read output, which is disadvantageous.

Because of the problem described above, even if the structure proposed in Patent Document 2 or the like is simply fabricated, the spin injection efficiency is not improved. Depending on the layer structure, the damping constant of the storage layer may be increased, resulting in a decrease in spin injection efficiency or a decrease in read output.

According to an embodiment of the present invention, there is provided a storage element in which the current used for writing can be decreased by improving the spin injection efficiency, and a memory including the storage element.

A storage element according to an embodiment of the present invention includes a storage layer which holds information based on a magnetization state of a magnetic body, an upper pinned magnetic layer disposed above the storage layer with an upper intermediate layer therebetween, and a lower pinned magnetic layer disposed below the storage layer with a lower intermediate layer therebetween, wherein one of the upper intermediate layer and the lower intermediate layer is an insulating layer which forms a tunnel barrier, the other intermediate layer is a laminate including an insulating layer and a nonmagnetic conductive layer, and the magnetization direction of the storage layer is varied by passing a current through the storage element in the lamination direction to enable recording of information on the storage layer.

A memory according to another embodiment of the present invention includes a storage element including a storage layer which holds information based on a magnetization state of a magnetic body, and a first wiring and a second wiring crossing over each other, wherein the storage element has the structure of the storage element according to the embodiment of the present invention described above, the storage element is disposed in the vicinity of a crossover of the first wiring and the second wiring and interposed between the first wiring and the second wiring, and a current flows through the storage element in the lamination direction through the first and second wirings.

According to the embodiment of the present invention, the storage element includes the storage layer which holds information based on a magnetization state of a magnetic body, the upper pinned magnetic layer disposed above the storage layer with the upper intermediate layer therebetween, and the lower pinned magnetic layer disposed below the storage layer with the lower intermediate layer therebetween, wherein the magnetization direction of the storage layer is varied by passing a current through the storage element in the lamination direction to enable recording of information on the storage layer. Consequently, it is possible to record information by spin injection by passing a current in the lamination direction.

Furthermore, one of the upper intermediate layer and the lower intermediate layer is an insulating layer which forms a tunnel barrier, and the other intermediate layer is a laminate including an insulating layer and a nonmagnetic conductive layer. Consequently, the spin injection efficiency can be improved and a satisfactory magnetoresistance effect can be obtained.

That is, since one of the intermediate layers is an insulating layer which forms a tunnel barrier, in a first magnetoresistive element including this intermediate layer, and the storage layer and the pinned magnetic layer sandwiching the intermediate layer, a high magnetoresistance effect can be obtained.

Furthermore, since the other intermediate layer is a laminate including an insulating layer and a nonmagnetic conductive layer, in a second magnetoresistive element including this intermediate layer, and the storage layer and the pinned magnetic layer sandwiching the intermediate layer, the spin injection efficiency can be improved because of the presence of the insulating layer, and also the magnetoresistance effect is satisfactorily decreased compared with the first magnetoresistive element.

Thus, the spin injection efficiency can be improved by laminating the magnetoresistive elements formed by the upper intermediate layer and the lower intermediate layer, and also the high magnetoresistance effect can be obtained by suppressing a decrease in the magnetoresistance effect of the entire storage element due to counteracting of the magnetoresistance effects of the upper and lower magnetoresistive elements.

Consequently, by improving the spin injection efficiency, it is possible to decrease the current (threshold current) for reversing the magnetization direction of the storage layer. Furthermore, since the rate of change in resistance (MR ratio) is increased because of the high magnetoresistance effect, the read signal strength can be increased.

According to the embodiment of the present invention, the memory includes the storage element including the storage layer which holds information based on a magnetization state of a magnetic body, and the first wiring and the second wiring crossing over each other, wherein the storage element has the structure of the storage element according to the embodiment of the present invention described above, the storage element is disposed in the vicinity of a crossover of the first wiring and the second wiring and interposed between the first wiring and the second wiring, and a current flows through the storage element in the lamination direction through the first and second wirings. Consequently, it is possible to record information by spin injection by passing a current through the storage element in the lamination direction through the first and second wirings.

Furthermore, because of spin injection, it is possible to decrease the current (threshold current) for reversing the magnetization direction of the storage layer of the storage element, and also satisfactory read signal strength can be obtained.

According to the embodiment of the present invention, by improving the spin injection efficiency, it is possible to decrease the current used for recording information. Thus, it is possible to decrease the power consumption of the entire memory. Therefore, it is possible to obtain a low power consumption memory that has not been available in the past.

Furthermore, since the read signal strength can be increased by increasing the rate of change in resistance (MR ratio), a sufficient operation margin can be obtained, and the storage element can be operated without errors. Therefore, a highly reliable memory that operates stably can be obtained.

### BRIEF DESCRIPTION OF THE DRAWINGS

FIG. 1 is a schematic perspective view of a memory according to an embodiment of the present invention;

FIG. 2 is a sectional view of a storage element shown in FIG. 1;

FIG. 3 is a schematic perspective view of a memory using magnetization reversal by spin injection;

FIG. 4 is a cross-sectional view of the memory shown in FIG. 3; and

FIG. 5 is a schematic perspective view showing a structure of a known MRAM.

### DESCRIPTION OF THE PREFERRED EMBODIMENTS

Prior to the description of the preferred embodiments of the present invention, a general outline of the present invention will be described.

According to an embodiment of the present invention, the magnetization direction of a storage layer of a storage element is reversed by the spin injection described above to record information. The storage layer is composed of a magnetic body, such as a ferromagnetic layer, and holds information based on a magnetization state (magnetization direction) of the magnetic body.

In the reversal of the magnetization direction of the magnetic layer by spin injection, the basic operation is to apply a current in an amount equal to or higher than a given threshold value to a storage element composed of a giant magnetoresistive element (GMR element) or a tunnel magnetoresistive element (MTJ element) perpendicular to the plane thereof. The polarity (direction) of the current depends on the magnetization direction to be reversed.

When a current whose absolute value is lower than the threshold value is applied, magnetization reversal does not occur.

In a known MRAM in which magnetization is reversed by a current-induced magnetic field, a current of several milliamperes or more is necessary.

In contrast, when magnetization is reversed by spin injection, since the threshold value of a write current is satisfactorily decreased as described above, this technique is obviously effective in decreasing the power consumption in integrated circuits.

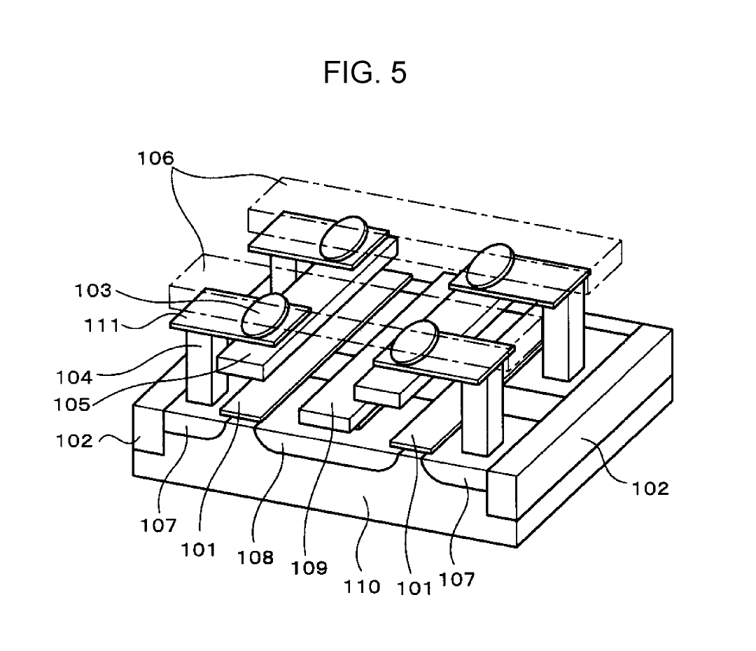

Furthermore, since the wiring for generating a current-induced magnetic field (represented by reference numeral 105 in FIG. 5), which is necessary in the known MRAM, is not necessary, the memory according to the embodiment of the present invention is advantageous in terms of the degree of integration over the known MRAM.

However, as described above, in the memory having the structure using magnetization reversal by spin injection, it is necessary to reverse the magnetization of the storage layer by performing spin injection using a current applied to the storage element.

Since information is written (recorded) by directly applying a current to the storage element, the storage element is connected to a selecting transistor to constitute a memory cell so that the memory cell is selected for writing. In such a case, the current flowing through the storage element is limited by the strength of the current that can be passed through the selecting transistor (saturation current of the selecting transistor).

Therefore, it is necessary to perform writing at a current value not more than the saturation current, and it is necessary to improve the spin injection efficiency so that the amount of current to be applied to the storage element can be decreased.

By fabricating a magnetic tunnel junction element (MTJ element) using a tunnel insulating layer as a nonmagnetic intermediate layer between a storage layer and a pinned magnetic layer, the rate of change in magnetoresistance (MR ratio) can be increased and the read signal strength can be increased compared with the case where a giant magnetoresistive element (GMR element) is fabricating using a nonmagnetic conductive layer.

Furthermore, according to Patent Documents 2 and 3, by disposing an upper pinned magnetic layer and a lower pinned magnetic layer above and below a storage layer and setting the magnetization directions of the upper and lower pinned magnetic layers to be antiparallel to each other, the spin injection efficiency can be improved.

However, even if simply an upper pinned magnetic layer and a lower pinned magnetic layer are disposed above and below a storage layer and the magnetization directions of the upper and lower pinned magnetic layers are set to be antiparallel to each other, the magnetoresistance effects of the upper and lower magnetoresistive elements, each including the storage layer, the upper or lower magnetic layer, and an intermediate layer, are counteracted, resulting in a decrease in the rate of change in magnetoresistance (MR ratio) of the entire storage element. Furthermore, because of the spin pumping phenomenon, the amount of current for reversing the magnetization of the storage layer (write threshold current) may be increased.

It is desirable to provide a structure of a storage element in which both the effect of increasing spin injection efficiency and a satisfactorily large rate of change in magnetoresistance (MR ratio) can be obtained.

According to an embodiment of the present invention, a storage element includes a magnetic layer (storage layer) which holds information based on a magnetization state and pinned magnetic layers whose magnetization directions are pinned.

An upper pinned magnetic layer and a lower pinned magnetic layer are provided above and below the storage layer to form upper and lower magnetoresistive elements. Thus, a laminated structure: pinned magnetic layer/intermediate layer/storage layer/intermediate layer/pinned magnetic layer, i.e., a dual-spin structure, is formed.

One of the two intermediate layers is an insulating layer which forms a tunnel barrier, and the other intermediate layer has a laminated structure including an insulating layer and a nonmagnetic conductive layer.

The laminated structure of the intermediate layer including the insulating layer and the nonmagnetic conductive layer is different from a GMR structure in which a conductive layer is used as the intermediate layer or a TMR structure in which an insulating layer is used as the intermediate layer. Consequently, the magnetoresistance effect becomes very low and is substantially lost.

Since the laminated structure is used for one of the intermediate layers, the problem of a decrease in the magnetoresistance effect, which is caused when tunnel insulating layers are used for both intermediate layers, does not occur.

In the laminated structure, because of the presence of the insulating layer in the intermediate layer, the spin pumping effect does not occur, and an increase in the threshold value of write current, which is caused by the spin pumping effect, does not occur.

Furthermore, since the pinned magnetic layer maintains the function as a spin-polarized current source, the spin injection effect can be obtained. Thus, the effect of an increase in the spin injection effect due to the provision of two pinned magnetic layers can be obtained, and the threshold value of a write current can be decreased. Because of the decrease in the current threshold, the power consumption of the memory including the storage element can be reduced.

As the material for the insulating layer constituting the intermediate layer having the laminated structure, a material containing, as a main component, an oxide or a nitride of at least one element selected from the group consisting of Al, Mg, Si, Ti, Cr, Zr, Hf, and Ta can be used.

As the material for the nonmagnetic conductive layer constituting the intermediate layer having the laminated structure, a material containing, as a main component, an element selected from the group consisting of Mg, Al, Si, Ge, Ti, V, Cr, Zr, Nb, Mo, Hf, Ta, W, Cu, Ag, Au, Ru, and Rh, or an alloy of two or more of these elements can be used.

Preferably, in the upper pinned magnetic layer and the lower pinned magnetic layer disposed above and below the storage layer, the magnetization directions of ferromagnetic layers closest to the storage layer are opposite each other.

In such a structure, the effect of improving the spin injection efficiency by employing the dual-spin structure is satisfactorily exhibited, and the spin injection efficiency can be further improved.

In the intermediate layer having the laminated structure including the insulating layer and the nonmagnetic conductive layer, the effect remains the same even if the deposition order is reversed. Either of the insulating layer and the nonmagnetic conductive layer may be placed closer to the storage layer. Furthermore, the laminated structure may include three or more layers as long as at least one nonmagnetic conductive layer and at least one insulating layer are included.

Except for the structure described above, the storage element may be designed so as to have the same structure as that of a known storage element in which information is recorded by spin injection.

Each of the upper and lower pinned magnetic layers above and below the storage layer has a structure in which the magnetization direction is pinned by a ferromagnetic layer only or using antiferromagnetic coupling between an antiferromagnetic layer and the ferromagnetic layer.

Furthermore, each of the upper and lower pinned magnetic layers above and below the storage layer has a single-layer structure composed of a ferromagnetic layer or a laminated ferrimagnetic structure in which a plurality of ferromagnetic layers are separated by a nonmagnetic layer.

In the case where the pinned magnetic layer has a laminated ferrimagnetic structure, since the sensitivity of the pinned magnetic layer to an external magnetic field can be decreased, it is possible to suppress unnecessary fluctuation of the magnetization of the pinned magnetic layer due to the external magnetic field, and the storage element is allowed to operate stably.

An embodiment of the present invention will now be described.

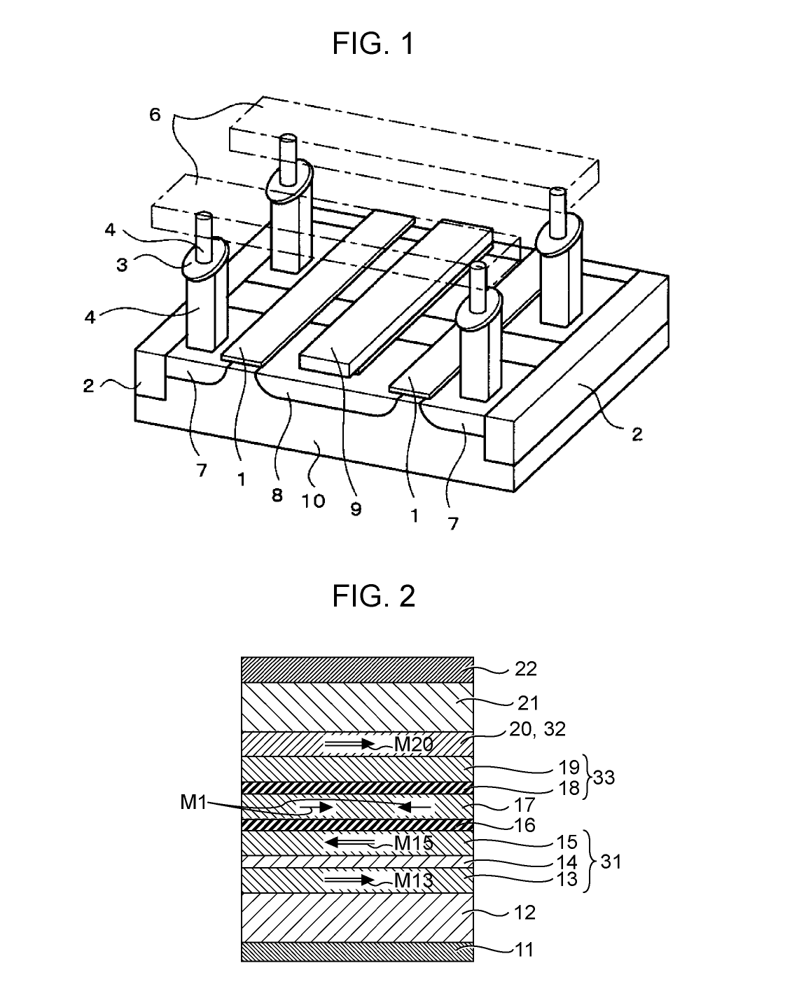

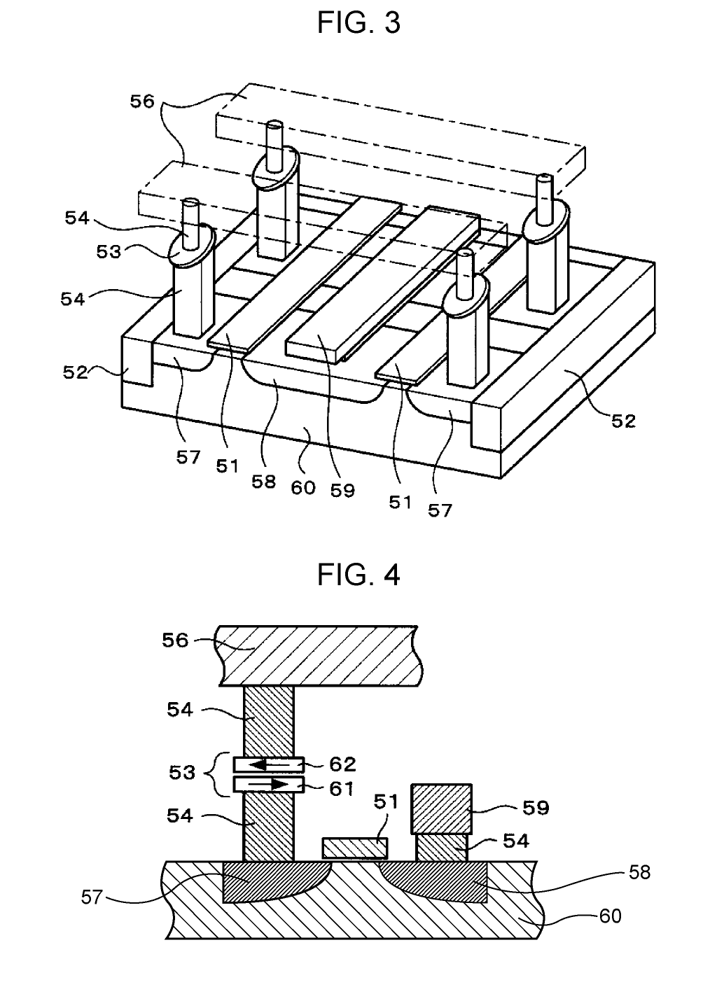

FIG. 1 is a schematic perspective view of a memory according to an embodiment of the present invention.

In this memory, two types of address wiring (e.g., word lines and bit lines) are arranged substantially perpendicular to each other, and a storage element capable of holding information based on a magnetization state is disposed in the vicinity of each crossover of these address wirings.

That is, a drain region 8, a source region 7, and a gate electrode 1 which constitute a selecting transistor for selecting a memory cell are disposed in each of the sections of a semiconductor substrate 10, such as a silicon substrate, the sections being isolated by element isolation layers 2. The gate electrode 1 also serves as one of the address wirings (e.g. word line) extending toward the back of the drawing.

The drain region 8 is designed so as to be shared by two adjacent selecting transistors in the row direction, and a wiring 9 is connected to the drain region 8.

A storage element 3 is disposed between the source region 7 and the other address wiring (e.g., bit line) 6 extending in the row direction above the storage element 3. The storage element 3 includes a storage layer composed of a ferromagnetic layer whose magnetization direction is reversed by spin injection. The storage element 3 is disposed in the vicinity of each crossover of the two types of address wirings 1 and 6.

The storage element 3 is connected to the bit line 6 and the source region 7 through an upper contact layer 4 and a lower contact layer 4, respectively.

By allowing a current to flow vertically through the storage element 3 through the two types of address wirings 1 and 6, the magnetization direction of the storage layer can be reversed by spin injection.

FIG. 2 is a sectional view of the storage element 3 according to the embodiment.

As shown in FIG. 2, the storage element 3 includes a storage layer 17 in which the direction of magnetization M1 is reversed by spin injection, a first pinned magnetic layer 31 disposed below the storage layer 17, and a second pinned magnetic layer 32 disposed above the storage layer 17. That is, two pinned magnetic layers 31 and 32 are disposed below and above the storage layer 17.

An antiferromagnetic layer 12 is disposed under the first pinned magnetic layer 31, and the magnetization direction of the first pinned magnetic layer 31 is pinned by the antiferromagnetic layer 12. An antiferromagnetic layer 21 is disposed on the second pinned magnetic layer 32, and the magnetization direction of the second pinned magnetic layer 32 is pinned by the antiferromagnetic layer 21.

The first pinned magnetic layer 31 has a laminated ferrimagnetic structure. Specifically, the first pinned magnetic layer 31 has a structure in which two ferromagnetic layers 13 and 15 are separated by a nonmagnetic layer 14 to form antiferromagnetic coupling.

In the first pinned magnetic layer 31, since the ferromagnetic layers 13 and 15 form the laminated ferrimagnetic structure, the magnetization M13 of the ferromagnetic layer 13 is directed rightward, and the magnetization M15 of the ferromagnetic layer 15 is directed leftward, the directions of the magnetization M13 and the magnetization M15 being opposite each other. Thus, in the first pinned magnetic layer 31, leakage magnetic flux from the ferromagnetic layer 13 and leakage magnetic flux from the ferromagnetic layer 15 are counteracted.

On the other hand, the second pinned magnetic layer 32 has a single-layer structure composed of a ferromagnetic layer 20 only.

An underlying layer 11 is disposed under the antiferromagnetic layer 12, and a cap layer 22 is disposed on the antiferromagnetic layer 21.

Since the first pinned magnetic layer 31 is designed to have the laminated ferrimagnetic structure, the sensitivity of the first pinned magnetic layer 31 to an external magnetic field can be decreased, and it is possible to suppress unnecessary fluctuation of the magnetization due to the external magnetic field.

As the material for each of the ferromagnetic layers 13, 15, and 20 in the pinned magnetic layers 31 and 32, an alloy containing, as main component, at least one element selected from the group consisting of Fe, Ni, and Co can be used. It may also be possible to incorporate an element, such as Nb, Zr, Ta, Ti, V, Cr, W, Mo, Hf, B, C, Al, Si, Ge, Mg, Mn, Cr, or Ga, into such an alloy.

In general, the saturation magnetization Ms of each of the ferromagnetic layers 13, 15, and 20 in the pinned magnetic layers 31 and 32 is suitably in a range of 200 to 2,000 emu/cc.

As the material for the nonmagnetic layer 14 constituting the laminated ferrimagnetic structure of the first pinned magnetic layer 31, Ru, Cu, Rh, or the like can be used.

The thickness of the nonmagnetic layer 14 is set so that the ferromagnetic layers 13 and 15 disposed at both sides of the nonmagnetic layer 14 can be antiferromagnetically coupled. Preferably, the thickness is in a range of 0.5 to 4 nm, although it depends on the material used.

As the material for each of the antiferromagnetic layers 12 and 21, an alloy between a metal, such as Fe, Ni, Pt, Ir, or Rh, and manganese, an oxide of cobalt or nickel, or the like can be used.

As the material for the storage layer 17, an alloy containing, as a main component, at least one element selected from the group consisting of Fe, Co, and Ni can be used, although not particularly limited thereto. It may also possible to incorporate an element, such as Nb, Zr, Ta, Ti, V, Cr, W, Mo, Hf, B, C, Al, Si, Ge, Mg, Mn, Cr, or Ga, into such an alloy.

As in the ferromagnetic layers 13, 15, and 20 in the pinned magnetic layers 31 and 32, in general, the saturation magnetization Ms of the ferromagnetic layer constituting the storage layer 17 is suitably in a range of 200 to 2,000 emu/cc.

In this embodiment, in particular, one of the two intermediate layers disposed between the storage layer 17 and the first pinned magnetic layer 31 and between the storage layer 17 and the second pinned magnetic layer 32 is composed of an insulating layer and the other is composed of a laminate including an insulating layer and a nonmagnetic conductive layer.

That is, an intermediate layer disposed between the storage layer 17 and the first pinned magnetic layer 31 below the storage layer 17 is composed of a tunnel insulating layer 16 only, and an intermediate layer 33 between the storage layer 17 and the second pinned magnetic layer 32 above the storage layer 17 is composed of a tunnel insulating layer 18 and a nonmagnetic conductive layer 19.

Since the intermediate layer under the storage layer 17 is composed of the tunnel insulating layer 16 only and the intermediate layer 33 on the storage layer 17 is composed of the tunnel insulating layer 18 and the nonmagnetic conductive layer 19, as described above, the spin injection efficiency can be improved and the rate of change in resistance (MR ratio) due to the magnetoresistance effect can be satisfactorily increased.

Furthermore, in this embodiment, the magnetization M15 of the ferromagnetic layer 15 of the first pinned magnetic layer 31 is directed leftward, and the magnetization M20 of the ferromagnetic layer 20 constituting the second pinned magnetic layer 32 is directed rightward, the directions of the magnetization M15 and the magnetization M20 being antiparallel to each other.

In the pinned magnetic layers 31 and 32 sandwiching the storage layer 17, the directions of the magnetizations M15 and M20 of the ferromagnetic layers 15 and 20 which are the ferromagnetic layers closest to the storage layer 17 are antiparallel to each other, and thus, the spin injection efficiency can be increased as described above. Consequently, the amount of current used for reversing the direction of the magnetization M1 of the storage layer 17 by spin injection can be decreased.

As the material for each of the tunnel insulating layers 16 and 18, a material containing, as a main component, an oxide or a nitride of at least one element selected from the group consisting of Al, Mg, Si, Ti, Cr, Zr, Hf, and Ta can be used.

As the material for the nonmagnetic conductive layer 19 of the intermediate layer 33 sandwiched between the storage layer 17 and the second pinned magnetic layer 32, an element selected from the group consisting of Mg, Al, Si, Ge, Ti, V, Cr, Zr, Nb, Mo, Hf, Ta, W, Cu, Ag, Au, Ru, and Rh, or an alloy of two or more of these elements can be used.

The storage element 3 according to this embodiment can be fabricated by a method in which layers from the underlying layer 11 to the cap layer 22 are continuously formed in a vacuum apparatus, and then a pattern of the storage element 3 is formed by micromachining, such as reactive ion etching or ion milling.

According to the embodiment described above, the storage element 3 has a structure in which the lower pinned magnetic layer 31 is disposed below the storage layer 17 with an intermediate layer therebetween, the upper pinned magnetic layer 32 is disposed above the storage layer 17 with an intermediate layer therebetween, the intermediate layer under the storage layer 17 is composed of the tunnel insulating layer 16 only, and the intermediate layer 33 on the storage layer 17 is composed of a laminate including the tunnel insulating layer 18 and the nonmagnetic conductive layer 19.

By forming the structure in which the lower pinned magnetic layer 31 is disposed below the storage layer 17 with the intermediate layer therebetween and the upper pinned magnetic layer 32 is disposed above the storage layer 17 with the intermediate layer therebetween, i.e., the dual-spin structure, it is possible to improve the spin injection efficiency compared with the single-spin structure in which only one pinned magnetic layer is disposed above or below a storage layer.

Since the intermediate layer under the storage layer 17 is composed of the tunnel insulating layer 16 only, a magnetoresistive element including the storage layer 17, the tunnel insulating layer 16, and the first pinned magnetic layer 31 has a structure of a tunnel magnetoresistive element (MTJ element). Thus, a large magnetoresistance effect can be obtained, and the rate of change in resistance (MR ratio) is increased.

Since the intermediate layer 33 on the storage layer 17 is composed of the laminate of the tunnel insulating layer 18 and the nonmagnetic conductive layer 19, in a magnetoresistive element including the storage layer 17, the intermediate layer 33 (18 and 19), and the second pinned magnetic layer 32, the spin pumping phenomenon is suppressed by the tunnel insulating layer 18, and thus the effect of improving spin injection efficiency is obtained. However, because of the presence of the nonmagnetic conductive layer 19, the magnetoresistance effect is very small. Consequently, the magnetoresistance effect is satisfactorily decreased compared with the lower magnetoresistive element.

Thus, in the entire storage element 3, the spin injection efficiency can be improved, and a satisfactorily high magnetoresistance effect can be obtained because the magnetoresistance effects of the two magnetoresistive elements, although opposite each other, are not substantially counteracted.

Furthermore, the magnetization M15 of the ferromagnetic layer 15 of the first pinned magnetic layer 31 is directed leftward, and the magnetization M20 of the ferromagnetic layer 20 of the second pinned magnetic layer 32 is directed rightward. Thus, the magnetizations M15 and M20 of the ferromagnetic layers 15 and 20, which are the ferromagnetic layers closest to the storage layer 17 in the pinned magnetic layers 31 and 32, are antiparallel to each other. Consequently, the spin injection efficiency can be increased.

Since the spin injection efficiency can be increased, the amount of current for reversing the direction of the magnetization M1 of the storage layer 17 by spin injection (threshold current for writing of information) can be decreased.

That is, in the memory provided with the storage element 3, it is possible to reduce power consumption.

Furthermore, since a satisfactorily large magnetoresistance effect can be obtained, the rate of change in resistance (MR ratio) of the storage element 3 is increased, resulting in an increase in read signal strength.

Thus, a sufficient operation margin can be obtained in the storage element 3, and the storage element 3 can be operated without errors. Therefore, a highly reliable memory that operates stably can be obtained.

In the intermediate layer composed of the laminate including the insulating layer and the nonmagnetic conductive layer, even if the lamination order is opposite to that of the storage element 3 shown in FIG. 2, the effect thereof does not change. That is, either one of the insulating layer and the nonmagnetic conductive layer may be disposed on the side of the storage layer.

Furthermore, the laminate may include three or more layers as long as at least one nonmagnetic conductive layer and at least one insulating layer are included.

Furthermore, the lower intermediate layer may be designed so as to have a laminated structure including an insulating layer and a nonmagnetic conductive layer and the upper intermediate layer may be designed to be a tunnel insulating layer.

With respect to the structure of the storage element according to the embodiment of the present invention, characteristics were investigated by selecting the materials and the thicknesses of the individual layers.

As shown in FIGS. 1 or 5, a memory actually includes, in addition to storage elements, a semiconductor circuit for switching, etc. Here, for the purpose of investigating the magnetoresistive characteristics of storage layers, a wafer provided with storage elements only was used.

### EXAMPLE 1

First, a thermal oxide film at a thickness of 2 μm was formed on a silicon substrate with a thickness of 0.575 mm, and a storage element 3 having a structure shown in FIG. 2 was formed thereon.

Specifically, in the storage element 3 shown in FIG. 2, the underlying layer 11 was formed of a Ta film with a thickness of 3 nm, the antiferromagnetic layer 12 was formed of a PtMn film with a thickness of 20 nm, the ferromagnetic layer 13 constituting the first pinned magnetic layer 31 was formed of a CoFe film with a thickness of 3 nm, the nonmagnetic layer 14 constituting the first pinned magnetic layer 31 having a laminated ferrimagnetic structure was formed of an Ru film with a thickness of 0.8 nm, the ferromagnetic layer 15 constituting the first pinned magnetic layer 31 was formed of a CoFeB film with a thickness of 3 nm, the tunnel insulating layer 16 was formed of an aluminum oxide film obtained by oxidizing an Al film with a thickness of 0.5 nm, the storage layer 17 was formed of a CoFeB film with a thickness of 3 nm, the tunnel insulating layer 18 constituting the intermediate layer 33 having a laminated structure was formed of an aluminum oxide film obtained by oxidizing an Al film with a thickness of 0.5 nm, the nonmagnetic conductive layer 19 constituting the intermediate layer 33 having the laminated structure was formed of an Ru film with a thickness of 3 nm, the ferromagnetic layer 20 constituting the second pinned magnetic layer 32 is formed of a CoFeB film with a thickness of 3 nm, the antiferromagnetic layer 21 was formed of a PtMn film with a thickness of 20 nm, and the cap layer 22 was formed of a Ta film with a thickness of 5 nm. A Cu film (corresponding to a word line described below) with a thickness of 100 nm was disposed between the underlying layer 11 and the antiferromagnetic layer 12 (not shown in the drawing).

That is, the laminate layer of the storage element 3 with the following structure (layer structure 1) was formed.

Layer Structure 1:

Ta(3 nm)/Cu(100 nm)/PtMn(20 nm)/CoFe(3 nm)/Ru(0.8 nm)/CoFeB(3 nm)/Al (0.5 nm)-Ox/CoFeB(3 nm)/Al(0.5 nm)-Ox/Ru(3 nm)/CoFeB(3 nm)/PtMn (20 nm)/Ta(5 nm)

In the layer structure described above, the composition of PtMn was Pt₅₀Mn₅₀ (subscript representing atomic percent), the composition of CoFe was Co₉₀Fe₁₀ (subscript representing atomic percent), and the composition of CoFeB was Co₇₂Fe₈B₂₀ (subscript representing atomic percent).

The individual layers other than the insulating layers 16 and 18 composed of the aluminum oxide films were formed by DC magnetron sputtering.

Each of the insulating layers 16 and 18 composed of the aluminum oxide (Al—Oₓ) films was formed by depositing a metallic aluminum film with a predetermined thickness by DC sputtering, and then oxidizing the metallic aluminum film by natural oxidation using an oxygen:argon flow ratio of 1:1 and a chamber gas pressure of 10 Torr. The oxidation time was set at 10 minutes.

After the individual layers of the storage element 3 were formed, heat treatment was performed at 10 kOe and 270° C., for 4 hours in a magnetic annealing furnace so that the PtMn films of the antiferromagnetic layers 12 and 21 were annealed for ordering.

Next, a word line portion was masked by photolithography, and a word line (lower electrode) was formed by performing selective etching using Ar plasma on the laminate layer in portions other than the word line. The portions other than the word line were etched at a depth of 5 nm from the surface of the substrate.

Subsequently, a mask having a pattern of the storage element 3 was formed using an electron beam lithography system, and the storage element 3 was formed by performing selective etching on the laminate layer. Portions other than the storage element 3 were etched to the level just above the Cu layer of the lower electrode.

In storage elements used for characteristics evaluation, since a sufficient current should flow through the storage element in order to generate spin torque necessary for magnetization reversal, a resistance value of the tunnel insulating layer should be suppressed. Therefore, the pattern of the storage element 3 was shaped like an ellipse with a minor axis of 0.09 μm and a major axis of 0.18 μm, and the sheet resistance (Ωμm²) of the storage element 3 was set to be 10 Ωμm².

Subsequently, portions other than the storage element 3 were insulated by forming an Al₂O₃ layer with a thickness of about 100 nm by sputtering.

Then, a bit line serving as an upper electrode and a measurement pad were formed by photolithography.

The storage element 3 was thereby prepared, which was used as a sample in Example 1.

### EXAMPLE 2

A laminate layer of a storage element 3 was formed as in Example 1 (layer structure 1) except that each of the first insulating layer 16 and the second insulating layer 18 was formed of a magnesium oxide (MgO) film with a thickness of 1 nm and the nonmagnetic conductive layer 19 was formed of a Cu film with a thickness of 6 nm.

Each of the MgO films was formed by RF sputtering in which using an MgO target, an oxide was directly deposited in an Ar gas.

That is, the laminate layer of the storage element 3 with the following structure (layer structure 2) was formed.

Layer Structure 2:

Ta(3 nm)/Cu(100 nm)/PtMn(20 nm)/CoFe(3 nm)/Ru(0.8 nm)/CoFeB(3 nm)/MgO (1 nm)/CoFeB(3 nm)/MgO(1 nm)/Cu(6 nm)/CoFeB(3 nm)/PtMn(20 nm)/Ta(5 nm)

Subsequently, the storage element 3 was prepared as in Example 1, which as used as a sample in Example 2.

### COMPARATIVE EXAMPLE 1

In the structure of a storage element 3 shown in FIG. 2, instead of the intermediate layer 33 including the tunnel insulating layer 18 and the nonmagnetic conductive layer 19 between the storage layer 17 and the second pinned magnetic layer 32, an intermediate layer composed of a nonmagnetic conductive layer 19 only was formed without including a tunnel insulating layer 18.

Furthermore, the ferromagnetic layer 15 of the first pinned magnetic layer 31 was formed of a CoFe film with a thickness of 3 nm, the storage layer 17 was formed of a CoFe film with a thickness of 3 nm, the nonmagnetic conductive layer 19 was formed of a Cu film with a thickness of 6 nm (the same as that in layer structure 2), and the ferromagnetic layer 20 of the second pinned magnetic layer 32 was formed of a CoFe film with a thickness of 3 nm.

Except for the above-mentioned points, a laminate layer of a storage element was formed as in Example 1 (layer structure 1).

That is, the laminate layer of the storage element with the following structure (layer structure 3) was formed.

Layer Structure 3:

Ta(3 nm)/Cu(100 nm)/PtMn(20 nm)/CoFe(3 nm)/Ru(0.8 nm)/CoFe(3 nm)/Al (0.5 nm)-Ox/CoFe(3 nm)/Cu(6 nm)/CoFe(3 nm)/PtMn(20 nm)/Ta(5 nm)

Subsequently, the storage element was prepared as in Example 1, which was used as a sample in Comparative Example 1.

### COMPARATIVE EXAMPLE 2

In the structure of a storage element 3 shown in FIG. 2, instead of the intermediate layer 33 including the tunnel insulating layer 18 and the nonmagnetic conductive layer 19 between the storage layer 17 and the second pinned magnetic layer 32, an intermediate layer composed of a tunnel insulating layer 18 only was formed without including a nonmagnetic conductive layer 19.

Furthermore, the ferromagnetic layer 15 of the first pinned magnetic layer 31 was formed of a CoFe film with a thickness of 3 nm, the storage layer 17 was formed of a CoFe film with a thickness of 3 nm, and the ferromagnetic layer 20 of the second pinned magnetic layer 32 was formed of a CoFe film with a thickness of 3 nm.

Except for the above-mentioned points, a laminate layer of a storage element was formed as in Example 1 (layer structure 1).

That is, the laminate layer of the storage element with the following structure (layer structure 4) was formed.

Layer Structure 4:

Ta(3 nm)/Cu(100 nm)/PtMn(20 nm)/CoFe(3 nm)/Ru(0.8 nm)/CoFe(3 nm)/Al (0.5 nm)-Ox/CoFe(3 nm)/Al(0.5 nm)-Ox/CoFe(3 nm)/PtMn(20 nm)/Ta(5 nm)

Subsequently, the storage element was prepared as in Example 1, which was used as a sample in Comparative Example 2.

### COMPARATIVE EXAMPLE 3

A storage element was formed as in the storage element 3 shown in FIG. 2 up to the storage layer 17, and a cap layer was formed on the storage layer. That is, the storage element of a single-spin type was formed in which the pinned magnetic layer was provided only below the storage layer.

Furthermore, the ferromagnetic layer 15 of the pinned magnetic layer 31 was formed of a CoFe film with a thickness of 3 nm, and the storage layer 17 was formed of a CoFe film with a thickness of 3 nm.

Except for the above-mentioned points, a laminate layer of a storage element was formed as in Example 1 (layer structure 1).

That is, the laminate layer of the storage element with the following structure (layer structure 5) was formed.

Layer Structure 5:

Ta(3 nm)/Cu(100 nm)/PtMn(20 nm)/CoFe(3 nm)/Ru(0.8 nm)/CoFe(3 nm)/Al (0.5 nm)-Ox/CoFe(3 nm)/Ta(5 nm)

Subsequently, the storage element was prepared as in Example 1, which was used as a sample in Comparative Example 3.

### COMPARATIVE EXAMPLE 4

A storage element was formed as in the storage element 3 shown in FIG. 2 up to the storage layer 17, and a cap layer was formed on the storage layer. That is, the storage element of a single-spin type was formed in which the pinned magnetic layer was provided only below the storage layer.

Except for the above-mentioned point, a laminate layer of a storage element was formed as in Example 2 (layer structure 2).

That is, the laminate layer of the storage element with the following structure (layer structure 6) was formed.

Layer Structure 6:

Ta(3 nm)/Cu(100 nm)/PtMn(20 nm)/CoFe(3 nm)/Ru(0.8 nm)/CoFeB(3 nm)/MgO (1 nm)/CoFeB(3 nm)/Ta(5 nm)

Subsequently, the storage element was prepared as in Example 2, which was used as a sample in Comparative Example 4.

With respect to the samples in the examples and the comparative examples described above, characteristics were evaluated as follows.

Prior to measurements, in order that the values of magnetic reversal current in the positive direction and the negative direction may be controlled to be symmetric, an arrangement was made so that a magnetic field could be applied to the storage element from the outside. Furthermore, the current to be passed through the storage element was set to be 1 mA or less, i.e., within a range in which the breakdown of the tunnel insulating layer was prevented.

(Measurement of Magnetization Reversal Current and MR Ratio)

In the presence of an applied current, the resistance of each storage element was measured. When the resistance of the storage element was measured, the temperature was set to a room temperature of 25° C., and the bias voltage applied to the terminal of the word line and the terminal of the bit line was adjusted to be 10 mV. Furthermore, while the amount of current applied to the storage element was changed, the resistance of the storage element was measured. A resistance-current curve was obtained form the measurement results. From the resistance-current curve, the value of current at which the resistance changed was obtained and defined as the value of magnetization reversal current for reversing magnetization. The measurement for obtaining the resistance-current curve was carried out with respect to the currents of both polarities (positive and negative directions), and the magnetization reversal current values of both polarities were obtained.

With respect to the same sample, the measurement for obtaining the resistance-current curve was repeated 50 times, and the average of the magnetization reversal current values was calculated.

Furthermore, from the resistance (high resistance) in a state in which the direction of the magnetization M15 of the ferromagnetic layer 15 on the storage layer 17 side of the pinned magnetic layer 31 and the direction of the magnetization M1 of the storage layer 17 were antiparallel to each other and the resistance was increased, and the resistance (low resistance) in a state in which the directions of the magnetization M15 and the magnetization M1 were parallel to each other and the resistance was decreased, using the expression (high resistance−low resistance)/low resistance, the rate of change in resistance was calculated, which was defined as the MR ratio. The measurement results are shown in Table 1 below.

TABLE 1

| | Magnetization | | |
|---|---|---|---|
| | reversal current | | |
| | value (Average) | MR ratio | Remarks |
| Example 1 | −0.4 mA, +0.4 mA | 50% | Use of alumina |
| | | | barrier |
| Example 2 | −0.3 mA, +0.3 mA | 150% | Use of MgO |
| | | | barrier |
| Comparative | −0.7 mA, +0.6 mA | 47% | TMR + GMR |
| Example 1 | | | |
| Comparative | −0.4 mA, +0.4 mA | 8% | TMR + TMR |
| Example 2 | | | |
| Comparative | −0.8 mA, +0.7 mA | 50% | Single alumina |
| Example 3 | | | barrier |
| Comparative | −0.6 mA, +0.5 mA | 150% | Single MgO |
| Example 4 | | | barrier |

As is evident from Table 1, in Examples 1 and 2, the magnetization reversal current value is small at 0.3 mA to 0.4 mA, and the MR ratio is as high as that of the single-spin type in Comparative Example 3 or 4. In Comparative Example 1, the upper intermediate layer includes the nonmagnetic conductive layer only, and a structure of a giant magnetoresistive element (GMR element), which has a lower MR ratio than a TMR element, is used. Thus, even if a dual-spin structure is employed, the magnetoresistance effect is not decreased. However, since the upper layer has the GMR structure, the spin pumping effect occurs, and the effect of improving spin injection efficiency by means of the dual-spin structure is not obtained, resulting in an increase in the magnetization reversal current value.

In Comparative Example 2, since both the upper and lower intermediate layers are tunnel insulating layers, the effect of improving spin injection efficiency by means of the dual-spin structure is satisfactorily obtained, and the magnetization reversal current value is small. However, since the magnetoresistance effects of the lower and upper TMR elements are counteracted, the entire storage element has a small MR ratio of 8%.

In Comparative Examples 3 and 4, since TMR elements of single-spin type are used, the magnetization reversal current value is large although the MR ratio is high.

Therefore, it has been found that by using the structure according to the embodiment of the present invention, as in Examples 1 and 2, excellent magnetization reversal characteristics can be obtained, and a MR ratio that is as high as that of the single-spin type can be obtained.

Furthermore, by using the structure in Example 1 or 2, it is possible to fabricate a storage element in which writing of information can be performed with a relatively small current of 0.5 mA or less, and thus a low power consumption memory that has not been available in the past can be provided.

In the present invention, the layer structure of the storage element 3 is not limited to that described in the embodiment above, and various layer structures may be employed.

In the embodiment described above, the pinned magnetic layer 31 has the laminated ferrimagnetic structure including the two ferromagnetic layers 13 and 15 and the nonmagnetic layer 14. For example, the lower pinned magnetic layer may be designed so as to have a single layer structure including a ferromagnetic layer. Moreover, the storage layer may be designed so as to have a laminated ferrimagnetic structure.

It should be understood by those skilled in the art that various modifications, combinations, sub-combinations and alterations may occur depending on design requirements and other factors insofar as they are within the scope of the appended claims or the equivalents thereof.

What is claimed is:

1. A storage element comprising:
a storage layer which holds information based on a magnetization state of a magnetic body;
an upper pinned magnetic layer disposed above the storage layer with an upper intermediate layer therebetween; and
a lower pinned magnetic layer disposed below the storage layer with a lower intermediate layer therebetween,
wherein one of the upper intermediate layer and the lower intermediate layer is an insulating layer which forms a tunnel barrier;
the other intermediate layer is a laminate including an insulating layer and a nonmagnetic conductive layer; and
the magnetization direction of the storage layer is varied by passing a current through the storage element in the lamination direction to enable recording of information on the storage layer.

2. The storage element according to claim 1, wherein, in the upper pinned magnetic layer and the lower pinned magnetic layer, the magnetization directions of ferromagnetic layers closest to the storage layer are opposite each other.

3. The storage element according to claim 1, wherein the insulating layer in each of the upper intermediate layer and the lower intermediate layer is composed of a material containing, as a main component, an oxide or a nitride of at least one element selected from the group consisting of Al, Mg, Si, Ti, Cr, Zr, Hf, and Ta.

4. The storage element according to claim 1, wherein the nonmagnetic conductive layer of one of the upper intermediate layer and the lower intermediate layer is composed of a material containing, as a main component, an element selected from the group consisting of Mg, Al, Si, Ge, Ti, V, Cr, Zr, Nb, Mo, Hf, Ta, W, Cu, Ag, Au, Ru, and Rh, or an alloy of two or more of these elements.

5. A memory comprising:
a storage element including a storage layer which holds information based on a magnetization state of a magnetic body; and
a first wiring and a second wiring crossing over each other,
wherein the storage element includes
an upper pinned magnetic layer disposed above the storage layer with an upper intermediate layer therebetween, and
a lower pinned magnetic layer disposed below the storage layer with a lower intermediate layer therebetween,
wherein one of the upper intermediate layer and the lower intermediate layer is an insulating layer which forms a tunnel barrier,
the other intermediate layer is a laminate including an insulating layer and a nonmagnetic conductive layer;
the storage element is disposed in the vicinity of a crossover of the first wiring and the second wiring and interposed between the first wiring and the second wiring; and
a current flows through the storage element in the lamination direction through the first and second wirings.
